(19) United States
(12) Patent Application Publication
(10) Pub. No.: US 2022/0085576 A1
(43) Pub. Date: Mar. 17, 2022

(54) Tunable Laser

(71) Applicant: Nippon Telegraph and Telephone Corporation, Tokyo (JP)

(72) Inventors: Takuma Aihara, Musashino-shi, Tokyo (JP); Shinji Matsuo, Musashino-shi, Tokyo (JP); Takaaki Kakitsuka, Musashino-shi, Tokyo (JP); Tai Tsuchizawa, Musashino-shi, Tokyo (JP); Tatsuro Hiraki, Musashino-shi, Tokyo (JP)

(21) Appl. No.: 17/421,467

(22) PCT Filed: Jan. 17, 2020
(86) PCT No.: PCT/JP2020/001400

§ 371 Date: Jul. 8, 2021

(30) Foreign Application Priority Data
Feb. 1, 2019 (JP) 2019-016870

(51) Int. Cl. H01S 5/323; H01S 5/026; H01S 5/042; H01S 5/0625; H01S 5/0687

(52) U.S. Cl. CPC H01S 5/323; H01S 5/0265; H01S 5/0687; H01S 5/06255; H01S 5/04256

(57) ABSTRACT

Provided is a tunable laser that prevents basic characteristics of the laser from deteriorating and enables a high-speed control of the oscillation wavelength. The tunable laser includes a semiconductor gain portion including a III-V compound semiconductor, an optical feedback portion configured to diffract light generated in the semiconductor gain portion and feed the diffracted light back to the semiconductor gain portion, and an optical modulation portion including an optical waveguide that contains doped indirect transition-type silicon. The semiconductor gain portion and the optical modulation portion are disposed so that optical modes thereof overlap each other, and the semiconductor gain portion includes an embedded active layer thin film of a type in which a current is injected in a lateral direction.

### TECHNICAL FIELD

The present invention relates to a tunable laser.

### BACKGROUND ART

Due to an increase in communication traffic on the Internet and the like, high-speed/large-capacity optical fiber transmission is in demand. The development of a digital coherent communication technology that utilizes a coherent optical communication technology and a digital signal processing technology has progressed, and a 100G system is in practical use. Such a communication system requires, as a local light source for communication and reception, a tunable light source capable of easily tuning the oscillation wavelength.

As a tunable light source, a tunable laser, in which a semiconductor gain portion and an optical filter that decides the oscillation wavelength are integrated on the same substrate, and an external resonator laser, in which a semiconductor gain portion and an optical filter are spatially and optically coupled to each other via a lens, have been realized. The former tunable laser is superior in view of downsizing of the system and stability of the oscillation mode, and the research and development thereof are presently being promoted.

Tunable lasers that have been reported are a distributed reflector (DBR) laser (NPL 1), a multielectrode distributed feedback (DFB) laser (NPL 2), a twin waveguide (DFB) laser (NPL 3), and the like.

### CITATION LIST

### Non Patent Literature

[NPL 1] S. Murata, et al., “TUNING FOR 1.5 μm WAVELENGTH TUNABLE DBR LASERS” ELECTRONICS LETTER 12 May 1988, Vol. 24 No. 10 pp. 577.
[NPL 2] M. Fukuda, et al., “Continuously Tunable Active layer thin film and Multisection DFB Laser with Narrow Linewicth and High Power” JOURNAL OF LIGHTWAVE TECHNOLOGY, VOL. 7 NO. 10, OCTOBER 1989.
[NPL 3] M. C, Amann, et al., “CONTINUOUSLY TUNABLE SINGLE-FREQUENCY LASER DIODE UTILISING TRANSVERSE TUNING SCHEME” ELECTRONICS LETTERS 22 Jun. 1989 Vol. 25 No. 13.

### SUMMARY OF THE INVENTION

### Technical Problem

A current injection structure is used as one of methods for controlling the oscillation wavelength of a semiconductor laser. The current injection structures of conventional semiconductor lasers employ a diode structure that includes a III-V semiconductor such as p-type InP and n-type InP. In this case, an electrical current is injected into the direct transition type III-V semiconductor and carriers are recoupled with each other, thereby emitting light. Since the light emission generates noise of the semiconductor laser, the spectrum line width of the laser deteriorates along with the oscillation wavelength control with current injection.

Also, an internal loss of a resonator increases because p-type InP, which has a large light absorption loss, is used as part of a waveguide that changes the refractive index. Accordingly, the conventional oscillation wavelength control with current injection using a III-V semiconductor has a problem that basic characteristics such as the light output and line width of the laser deteriorate.

As one of the methods for controlling the oscillation wavelength of a semiconductor laser, there is also a method in which a part of a waveguide is heated by a heater and the refractive index is changed based on the thermo-optical effect, thereby changing the oscillation wavelength. This method hardly causes a deterioration in basic characteristics of the semiconductor laser but has a problem that high-speed wavelength control is difficult and thus an application of the method to an optical packet switch, which requires high-speed response, and the like is difficult.

The present invention was made in view of the above-described problems, and an object thereof is to provide a tunable laser that prevents basic characteristics of the laser from deteriorating, and enables high-speed control of the oscillation wavelength.

### Means for Solving the Problem

A tunable laser according to one aspect of the present invention includes: a semiconductor gain portion including a III-V compound semiconductor; an optical feedback portion configured to diffract light generated in the semiconductor gain portion and feed the diffracted light back to the semiconductor gain portion; and an optical modulation portion including an optical waveguide that contains doped indirect transition-type silicon, wherein the semiconductor gain portion and the optical modulation portion are disposed so that optical modes thereof overlap each other.

### Effects of the Invention

According to the present invention, it is possible to provide a tunable laser that prevents basic characteristics of the laser from deteriorating, and enables high-speed control of the oscillation wavelength.

### BRIEF DESCRIPTION OF DRAWINGS

FIG. 1 is a diagram schematically illustrating a cross section of a tunable laser according to a first embodiment of the present invention.

FIG. 2 is a diagram illustrating the tunable laser shown in FIG. 1 with circuit symbols.

FIG. 3 is a diagram schematically illustrating a cross section of a tunable laser according to a second embodiment of the present invention.

FIG. 4 is a diagram illustrating an example of a calculation result of a light intensity distribution of the tunable laser shown in FIG. 3.

FIG. 5 is a diagram illustrating a relationship between the film thickness of a III-V layer, shown in FIG. 3, that includes an active layer, and a confinement factor.

FIG. 6 is a diagram schematically illustrating a cross section of a modification of the tunable laser shown in FIG. 3.

FIG. 7 is a diagram schematically illustrating a cross section of a modification of the tunable laser shown in FIG. 3.

FIG. 8 is a diagram schematically illustrating a cross section of a modification of the tunable laser shown in FIG. 7.

FIG. 9 is a diagram schematically illustrating a cross section of a modification of the tunable laser shown in FIG. 8.

FIG. 10 is a diagram schematically illustrating a cross section of a modification of the tunable laser shown in FIG. 1.

FIG. 11 is a diagram schematically illustrating a cross section of a modification of the tunable laser shown in FIG. 10.

FIG. 12 is a diagram schematically illustrating a cross section of a modification of the tunable laser shown in FIG. 3.

FIG. 13 is a diagram schematically illustrating a cross section of a modification of the tunable laser shown in FIG. 12.

FIG. 14 is a diagram schematically illustrating a cross section of a tunable laser that includes, instead of a semiconductor gain portion shown in FIG. 3, a semiconductor gain portion of a type in which a current is injected in a vertical direction.

FIG. 15 is a diagram schematically illustrating an example of a configuration of a tunable laser that uses a DBR mirror.

### DESCRIPTION OF EMBODIMENTS

Hereinafter, embodiments of the present invention will be described with reference to the drawings. The same reference numerals are given to the same components throughout a plurality of drawings, and redundant description may be omitted.

### First Embodiment

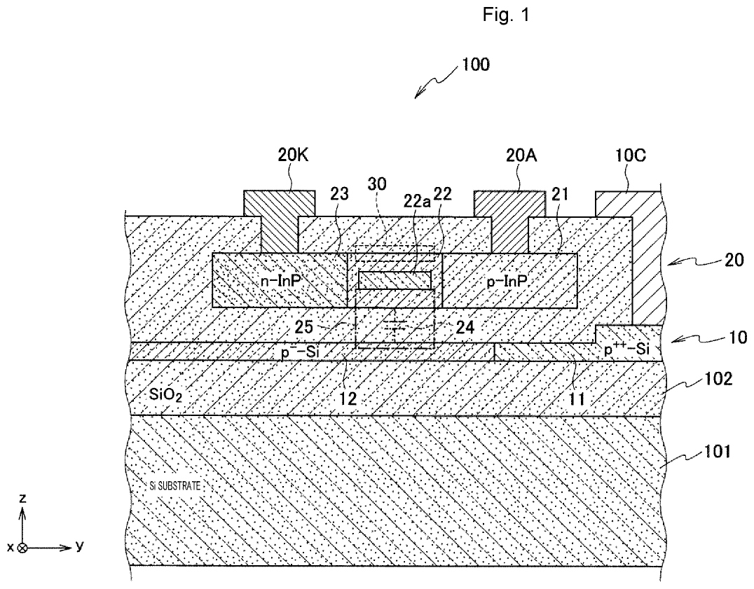

FIG. 1 is a diagram schematically illustrating a cross section of a tunable laser according to a first embodiment of the present invention. FIG. 1 shows a schematic cross-sectional view with a surface of the tunable laser serving as an x-y plane. In the figure, x is defined as the depth direction of the drawing, y is defined as the left-right direction thereof, and z is defined as the thickness direction thereof.

A tunable laser 100 shown in FIG. 1 is obtained by stacking a Si substrate 101, a SiO₂ film 102, an optical modulation portion 10, a semiconductor gain portion 20, and an optical feedback portion in this order from the bottom in z direction. The optical modulation portion 10 and the optical gain portion 20 have an elongated shape in the x direction.

The SiO₂ film 102 has the thickness of about 3 μm and constitutes a lower cladding layer. The optical modulation portion 10 is disposed on the SiO₂ film 102. The optical modulation portion includes an electrode 10C, a diffusion electrode 11, and a modulation/diffusion portion 12. The diffusion electrode 11 and the modulation/diffusion portion 12 are doped indirect transition-type silicon semiconductors.

The electrode 10C and the diffusion electrode 11 are ohmically connected to each other. Also, on the side of the diffusion electrode 11 opposite to the electrode 10C, the modulation/diffusion portion 12 is formed that is doped with a smaller amount of impurity than that with which the diffusion electrode 11 is doped.

The semiconductor gain portion 20 includes an I layer 22 between p-type InP (p-InP) 21 and n-type InP (n-InP) 23, which are impurity-doped III-V semiconductors. The I layer 22 is an intrinsic semiconductor and includes an active layer 22a. The material of the active layer 22a is InGaAsP, for example.

The p-InP 21 is ohmically connected to an anode electrode 20A. Also, the n-InP 23 is ohmically connected to a cathode electrode 20K.

The semiconductor gain portion 20 shown in FIG. 1 constitutes an embedded active layer thin film of a type in which a current is injected in the lateral direction, for example. Note that the semiconductor gain portion 20 may be configured so that a current is caused to flow in the thickness direction. The configuration in which a current is caused to flow in the thickness direction will be described later.

The I layer 22, the active layer 22a, the p-InP 21, and the n-InP 23, each has an elongated shape in the x direction.

The I layer 22 constitutes an upper cladding layer of the active layer thin film structure. On the upper cladding layer, the optical feedback portion 30 is formed that diffracts light whose phase is shifted by, e.g., λ/4 and feeds the diffracted light back to the semiconductor gain portion 20. With the optical feedback portion 30, a single mode oscillation is realized.

A portion of the modulation/diffusion portion 12 of the optical modulation portion 10 is opposed to the I layer 22 with an insulating film (SiO₂) interposed therebetween, and these opposing portions form a capacitance 24. The portions of the I layer 22 and the modulation/diffusion portion 12 that form the capacitance 24 constitute an optical waveguide 25 that contains doped indirect transition-type silicon.

The refractive index of the optical waveguide 25 can be changed by applying a voltage between the cathode electrode 20K and the electrode 10C so that carriers are accumulated in the capacitance 24. Light is confined in the optical waveguide 25.

To realize effective carrier accumulation, the thickness of the insulating film (SiO₂) that forms the capacitance 24 is preferably about, e.g., 10 nm. Also, the active layer 22a and the optical modulation portion 10 are disposed at a distance at which the optical modes thereof overlap each other. The expression “the optical modes thereof overlap each other” means that light generated in the active layer 22a affects the optical modulation portion 10. The phenomenon in which light generated in the active layer 22a is confined in the optical waveguide 25 will be described later.

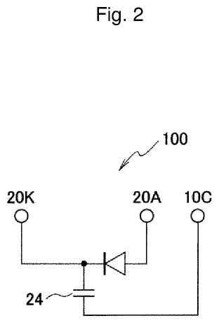

FIG. 2 is a diagram illustrating the tunable laser 100 with circuit symbols. As shown in FIG. 2, the carrier accumulation-type tunable laser 100 can be expressed by a circuit in which the cathode electrode 20K and the electrode 10C are connected to each other via the capacitance 24. In a current injection-type tunable laser, which will be described later, the portion of the capacitance 24 can be expressed by a diode that is independent from a PN junction (diode) of the semiconductor gain portion 20.

As described above, the tunable laser 100 includes the semiconductor gain portion 20 including a III-V compound semiconductor, the optical feedback portion 30 that diffracts light generated in the semiconductor gain portion 20 and feeds the diffracted light back to the semiconductor gain portion 20, and the optical modulation portion 10 including the optical waveguide 25 that contains doped indirect transition-type silicon. The semiconductor gain portion 20 and the optical modulation portion 10 are disposed so that the optical modes thereof overlap each other.

Thus, the tunable laser 100 has a structure in which current injection into the active layer 22a and carrier accumulation in the optical waveguide 25 can be performed separately. The carrier accumulation according to the present embodiment does not involve light emission, and thus wavelength control with carrier accumulation does not cause noise of the semiconductor laser. Also, the optical waveguide 25 is an indirect transition-type silicon semiconductor, and thus, it is possible to reduce a loss. Also, the refractive index is changed based on a change in the majority carrier density, and thus it is possible to realize high-speed refractive index change, that is, high-speed wavelength control.

### Second Embodiment

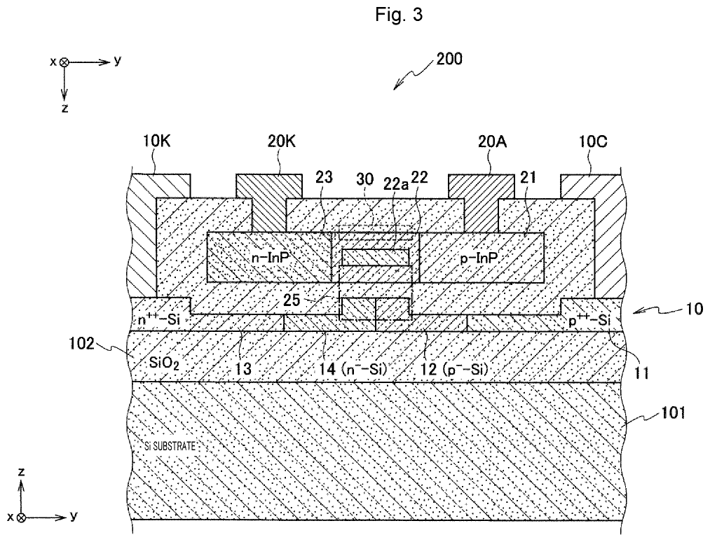

FIG. 3 is a diagram schematically illustrating a cross section of a tunable laser according to a second embodiment of the present invention. A tunable laser 200 shown in FIG. 3 is capable of changing the refractive index of the optical waveguide 25 by performing current injection-type carrier accumulation.

Therefore, the tunable laser 200 differs from the tunable laser 100 (FIG. 1) in that the tunable laser 200 includes an optical modulation portion 10 that performs current injection-type carrier accumulation. The optical modulation portion 10 shown in FIG. 2 includes a diffusion electrode 13 (n⁺⁺-Si) and a modulation/diffusion portion 14 (n⁻-Si) that are doped with an indirect transition-type donor. “n⁺⁺” denotes a region with the higher donor concentration, and “n⁻” denotes a region with the lower donor concentration. The diffusion electrode 13 is ohmically connected to the electrode 10K.

As is clear from the reference numerals, an electrode 10C, a diffusion electrode 11, and a modulation/diffusion portion 12 are equivalent to those of the tunable laser 100 (FIG. 1). Note however that an end portion on a side of the modulation/diffusion portion 12 that is opposite to the electrode 10C forms a PN junction with the modulation/diffusion portion 14. The PN junction is rib-shaped while extending in the x direction, and forms a part of the optical waveguide 25.

The optical modulation portion 10 shown in FIG. 3 is a silicon optical modulator, which is known in the field of silicon photonics. Similar to the tunable laser 100, a semiconductor gain portion 20 is disposed on the top of the optical modulation portion 10. The semiconductor gain portion 20 is equivalent to that of the tunable laser 100 (FIG. 1).

The distance between the optical modulation portion 10 and the I layer 12 of the semiconductor gain portion 20 is set to about, e.g., 100 nm such that the optical modes of both the active layer 12a and the optical modulation portion 10 overlap each other.

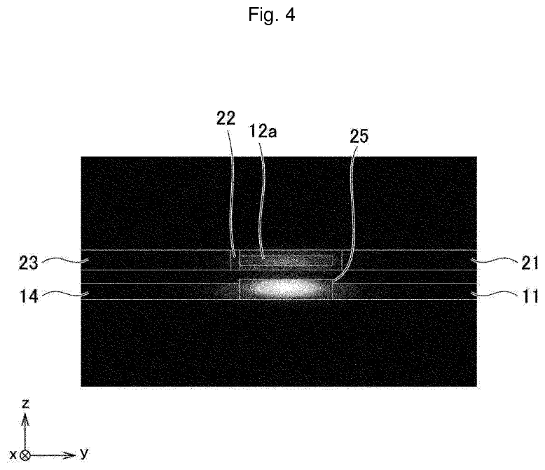

FIG. 4 is a diagram illustrating a calculation result of a light intensity distribution of the tunable laser 200. In FIG. 4, light intensities are shown in gray scale. A white portion indicates a region with a higher light intensity.

As shown in FIG. 4, the light intensity of the PN junction portion is high, the PN junction portion being a portion at which the modulation/diffusion portion 12 and the modulation/diffusion portion 14 are joined each other. The modulation/diffusion portion 12 and the modulation/diffusion portion 14 are indirect transition-type semiconductors, and thus, the portions are regions in which no light is emitted even when a current is caused to flow therebetween (even when a current is injected).

Also, the effective refractive index of the optical waveguide 25 can be changed by injecting a current into the optical modulation portion 10 to change the refractive index of the optical waveguide 25. The optical confinement coefficient in the optical waveguide 25 of the tunable laser 200 is about 50%, and the optical confinement coefficient in the active layer 22a is about 12%. It is apparent that light is distributed over the PN junction portion of the indirect transition-type in this way, and the optical modes of the semiconductor gain portion 20 and the optical modulation portion 10 overlap each other.

By injecting a current into the optical modulation portion 10, the refractive index of the optical waveguide 25 is changed and the laser can be oscillated while ensuring a gain. Accordingly, it is possible to control the wavelength of the laser.

Note that a refractive index change Δn of silicon with respect to a carrier density change ΔN is disclosed in, for example, a reference literature (A. Singh, “Free charge carrier induced refractive index modulation of crystalline Silicon”, 7th IEEE International Conference on Group IV Photonics, P1. 13, 2010). An is about −1.1×10⁻² when the wavelength λ=1550 nm and ΔN=1.0×10¹⁹ cm⁻³ are satisfied.

When the Bragg wavelength shift Δλ_{B} is estimated by taking into consideration of the optical confinement coefficient in silicon on the basis of the expression below, Δλ_{B}=6 nm is obtained.

λ_{B}=2n_{eff}Λ (1)

While n_{eff} is the effective refractive index of the optical waveguide 25, A is a diffraction grating period of the optical feedback portion 30.

In other words, by injecting a current into the optical modulation portion 10, the oscillation wavelength can be changed by about 6 nm. If the oscillation wavelength is to be changed by a larger amount, it is necessary to increase the optical confinement coefficient in the optical waveguide 25.

In order to increase the optical confinement coefficient in the optical waveguide 25, it is necessary to increase the cross-sectional area of the optical waveguide 25. That is to say, it is effective that the optical waveguide 25 has an increased thickness (increased height of the rib shape) and an increased width.

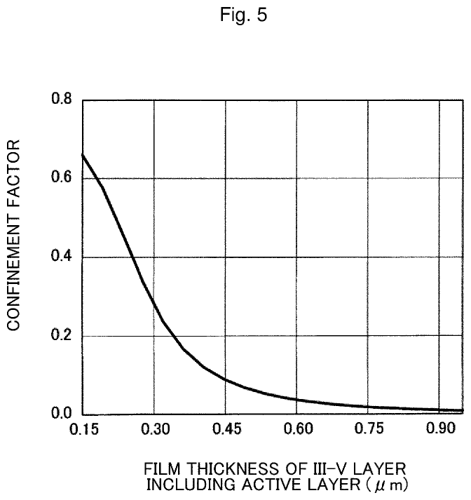

FIG. 5 is a diagram illustrating a relationship between the film thickness of the semiconductor gain portion 20 and the optical confinement coefficient. A horizontal axis indicates the film thickness (μm) of the semiconductor gain portion 20, and a vertical axis indicates a factor (confinement factor) for which light is confined in the optical waveguide 25.

As shown in FIG. 5, characteristics are such that, as the film thickness of the semiconductor gain portion 20 is reduced, the confinement factor becomes greater. Accordingly, the semiconductor gain portion 20 preferably has an embedded active layer thin film structure.

A DFB (Distributed Feedback) laser with high output/narrow line width is designed so that the laser includes a long resonator. Such a design of a DFB with a high coupling factor including a long resonator is not advantageous in view of spatial hole burning.

Accordingly, typical DFB lasers with high output/narrow line width employ a diffraction grating having a low coupling factor. On the other hand, in view of the wavelength change, it is advantageous to increase the optical confinement coefficient in the optical waveguide 25.

Accordingly, preferably, the diffraction grating is formed on the embedded active layer thin film structure of the semiconductor gain portion 20 that has a relatively low optical confinement, so as to have a low coupling factor. To realize a low coupling factor, it is preferable to form the diffraction grating using a SiN film or a SiON film, which is a thin film having a low permittivity.

In this case, the diffraction grating is formed by using an ECR plasma CVD method, which can be performed with a low deposition temperature. Also, deuterium silane gas is preferably used as raw material gas, in order to suppress N—H group absorption in an optical communication wavelength band.

In other words, the diffraction grating formed on the semiconductor gain portion 20 includes of a SiN film or SiON film that contains deuterium. Accordingly, it is possible to suppress N—H group absorption in an optical communication wavelength band.

(Modification 1)

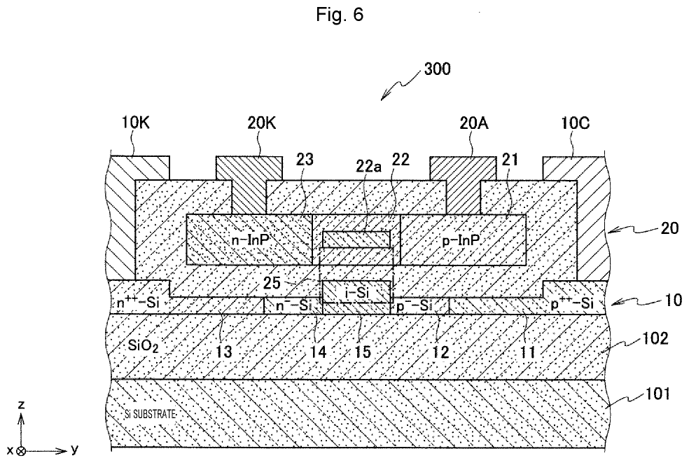

FIG. 6 is a diagram schematically illustrating a cross section of a tunable laser obtained by modifying the tunable laser 200 (FIG. 3). In a tunable laser 300 shown in FIG. 5, a PN junction portion in which the modulation/diffusion portion 12 and the modulation/diffusion portion 14 are joined each other includes an intrinsic semiconductor (i-Si) 26.

Since the intrinsic semiconductor 26 includes no impurity, the loss of the optical waveguide 25 can be reduced and the laser light intensity can be increased.

(Modification 2)

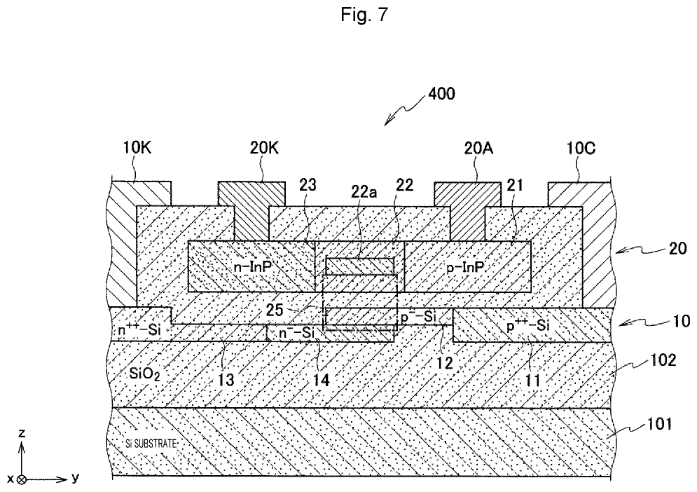

FIG. 7 is a diagram schematically illustrating a cross section of a tunable laser obtained by modifying the tunable laser 200 (FIG. 3). In a tunable laser 400 shown in FIG. 7, a PN junction portion in which the modulation/diffusion portion 12 and the modulation/diffusion portion 14 are joined each other is formed in a vertical direction. In this manner, a current to be injected into the optical modulation portion 10 may be caused to flow in the vertical direction. The same function and effects as those in the tunable laser 200 (FIG. 3) can be obtained.

(Modification 3)

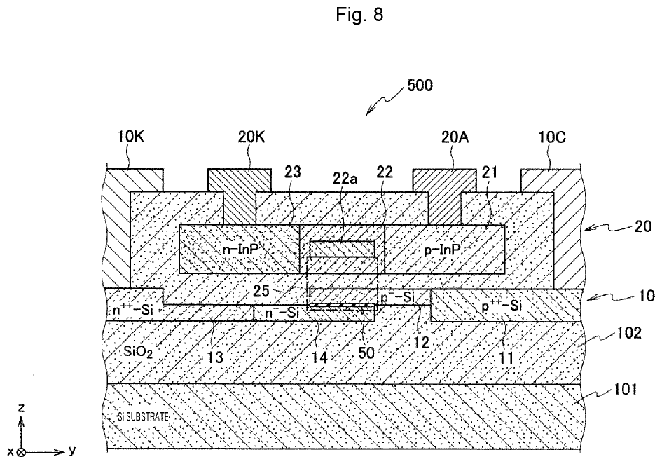

FIG. 8 is a diagram schematically illustrating a cross section of a tunable laser obtained by modifying the tunable laser 400 (FIG. 7). A tunable laser 500 shown in FIG. 8 includes an insulating film between the modulation/diffusion portion 12 and the modulation/diffusion portion 14 that are formed in the vertical direction. Thus, the optical modulation portion 10 may also include a carrier accumulation-type modulator, as similar to the tunable laser 100 (FIG. 1).

(Modification 4)

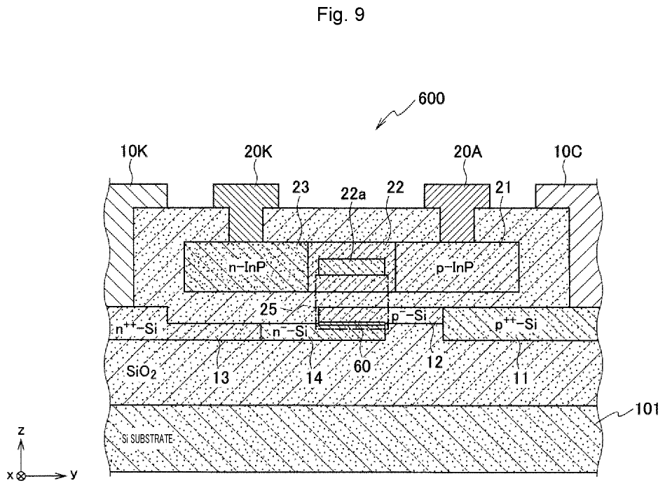

FIG. 9 is a diagram schematically illustrating a cross section of a tunable laser obtained by modifying the tunable laser 500 (FIG. 8). A tunable laser 600 shown in FIG. 9 includes an electro-optic material 60, instead of the insulating film 50 of the tunable laser 500 (FIG. 8).

Thus, the tunable laser 600 may be provided with a modulator using the electro-optic effect (for example, Pockels effect). Examples of the electro-optic material include KDP (potassium dihydrogen phosphate), LiNBO₃, and LiTaO₃.

(Modification 5)

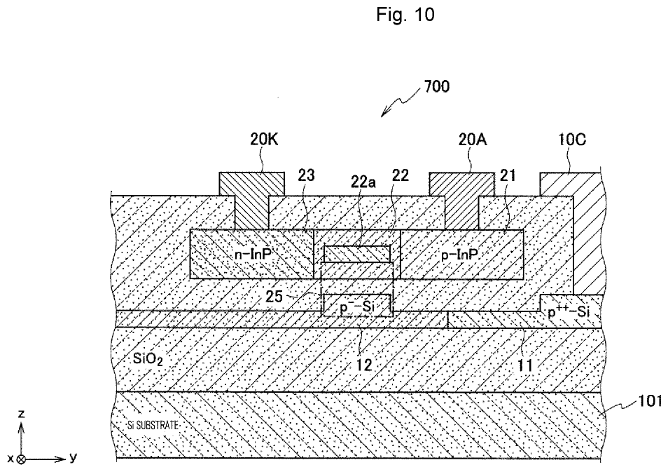

FIG. 10 is a diagram schematically illustrating a cross section of a tunable laser obtained by modifying the tunable laser 100 (FIG. 1). In a tunable laser 700 shown in FIG. 10, the portion of the modulation/diffusion portion 12 that is opposed to the active layer 22a is rib-shaped.

By causing the portion of the modulation/diffusion portion 12 to be rib-shaped, it is possible to increase the optical confinement factor in the optical waveguide 25 (relative to that in the tunable laser 100 (FIG. 1)).

(Modification 6)

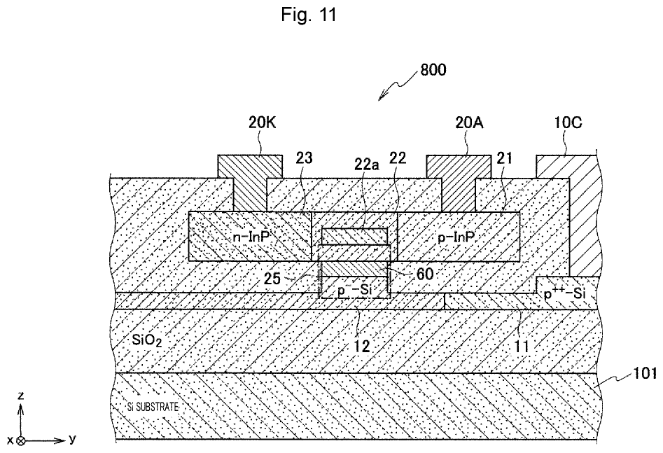

FIG. 11 is a diagram schematically illustrating a cross section of a tunable laser obtained by modifying the tunable laser 700 (FIG. 10). A tunable laser 800 shown in FIG. 11 includes the electro-optic material 60, instead of the insulating film (SiO₂) between the rib-shaped modulation/diffusion portion 12 and the I layer 22 of the tunable laser 700 (FIG. 10).

Thus, the carrier accumulation-type tunable laser 800 may be provided with a modulator using the electro-optic effect (for example, Pockels effect).

(Modification 7)

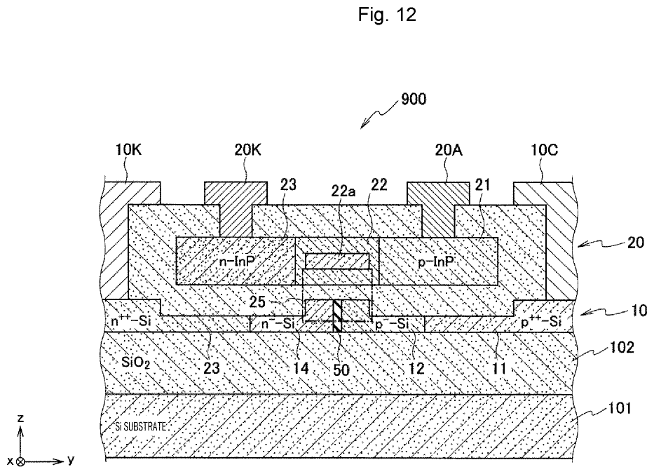

FIG. 12 is a diagram schematically illustrating a cross section of a tunable laser obtained by modifying the tunable laser 200 (FIG. 3). A tunable laser 900 shown in FIG. 12 includes the insulating film 50 that is inserted between the modulation/diffusion portion 12 and the modulation/diffusion portion 14.

As shown in FIG. 12, the carrier accumulation-type tunable laser 900 may also be provided with the insulating film 50 formed in the PN junction formed in the y direction.

(Modification 8)

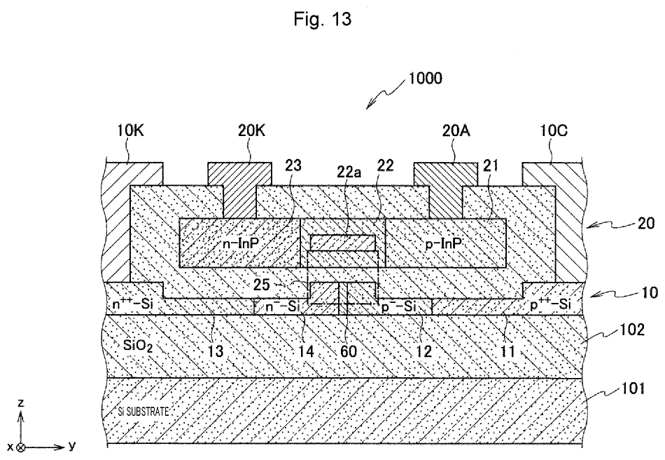

FIG. 13 is a diagram schematically illustrating a cross section of a tunable laser obtained by modifying the tunable laser 900 (FIG. 12). A tunable laser 1000 shown in FIG. 13 includes the electro-optic material 60, instead of the insulating film 50 formed between the modulation/diffusion portion 12 and the modulation/diffusion portion 14.

(Modification 9)

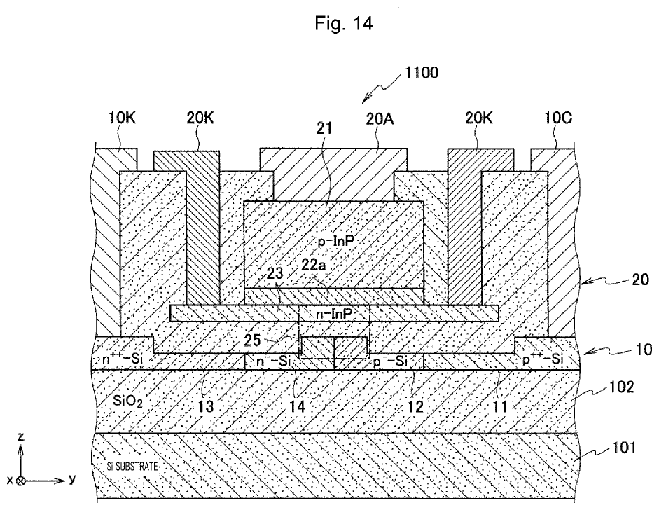

FIG. 14 is a diagram schematically illustrating a cross section of a tunable laser that includes a semiconductor gain portion 20 of a type in which a current is injected in the vertical direction. As shown in FIG. 14, the semiconductor gain portion 20 may be formed by stacking the p-type InP (p-InP) 21 of an impurity-doped III-V semiconductor, the I layer 22, and the n-type InP (n-InP) 23 in the vertical direction.

In this case, the thickness of the p-type InP (p-InP) 21 is set to about 1 to 2 μm in order to prevent light absorption in the anode electrode 20A. Also, since the n-type InP (n-InP) 23 is present in the optical waveguide 25, the optical confinement in the optical waveguide 25 is reduced. Accordingly, it is necessary to increase the cross-sectional area of the optical waveguide 25.

Note that the optical modulation portion 10 may also be replaced by any of the optical modulation portions of the above-described embodiments and modifications.

The electrodes 10C, 10K, and 20A (anode electrodes), and 20K (a cathode electrode) of the semiconductor gain portion 20 and the optical modulation portion 10 of each of the tunable lasers according to the above-described embodiments and modifications are disposed on a surface on the semiconductor gain portion 20 side. Accordingly, it is possible to realize easy implementation of the tunable laser.

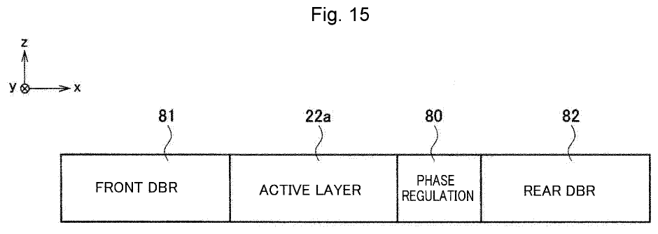

The above-described embodiments have been described on the basis of an example in which a DFB laser is used, but the present invention is not limited to this example. For example, a configuration in which a DBR mirror is used as shown in FIG. 15 is also possible. In this case, the active layer 22a and a phase regulation portion 80 are aligned in the x direction, and a front DBR 81 and a rear DBR 82 are disposed on the front and rear sides of them. The phase regulation portion 80 does not include a diffraction grating.

The front DBR 81 and the rear DBR 82 are realized by forming a diffraction grating on a waveguide of a silicon optical modulator. The Bragg wavelength can be changed by injecting a current into the silicon optical modulator in the DBR region, and thus, it is possible to change the oscillation wavelength. The diffraction grating is formed on the upper surface or a side surface of the optical waveguide 25, or at another position to which it can be optically coupled.

Also, the mirror is not limited to the DBR mirror. For example, a loop mirror may also be used. Also, a configuration is also possible in which a lattice filter (not shown) and a ring filter (not shown) are combined each other. In this case, by changing the refractive indices of the waveguides that constitute the lattice filter and the ring filter, the wavelength characteristics of these filters can be changed, thereby making it possible to change the oscillation spectrum.

Note that the above-described embodiments have been described on the basis of an example in which a current is injected into the optical modulation portion 10, but it is also possible to apply a reverse bias voltage and pull carriers so that the refractive index is changed. In this case, the amount of change in the carrier density is less than that in a case where a current is injected, but a high-speed operation is possible.

Also, the diffraction grating has been described on the basis of an example in which the diffraction grating is formed on the semiconductor gain portion 20, but the present invention is not limited to this example. The diffraction grating may also be formed on any of the upper and side surfaces of the optical waveguide 25 and other positions to which it can be optically coupled.

Thus, the present invention of course includes various embodiments that have not been described here, and the like. Accordingly, the technical scope of the present invention is to be defied only by matters specifying the invention according to the claims appropriate from the above description.

### REFERENCE SIGNS LIST

100 to 1100: Tunable laser
10: Optical modulation portion
10C, 10K: Electrode
20: Semiconductor gain portion
20A: Anode electrode
20K: Cathode electrode
21: p-type InP (p-InP)
22: I layer
22a: Active layer
23: n-type InP (n-InP)
24: Capacitance
25: Optical waveguide
26: Intrinsic semiconductor (i-Si)
30: Optical feedback portion
50: Insulating film
60: Electro-optic material

1. A tunable laser comprising:
a semiconductor gain portion including a III-V compound semiconductor;
an optical feedback portion configured to diffract light generated in the semiconductor gain portion and feed the diffracted light back to the semiconductor gain portion; and
an optical modulation portion including an optical waveguide that contains doped indirect transition-type silicon, wherein
the semiconductor gain portion and the optical modulation portion are disposed so that optical modes thereof overlap each other.

2. The tunable laser according to claim 1, wherein
the semiconductor gain portion includes an embedded active layer thin film of a type in which a current is injected in a lateral direction.

3. The tunable laser according to claim 1, wherein
the optical waveguide of the optical modulation portion includes a silicon optical modulator that includes a rib structure.

4. The tunable laser according to claim 1, wherein
the optical feedback portion includes a diffraction grating formed on the semiconductor gain portion.

5. The tunable laser according to claim 4, wherein
the diffraction grating includes a SiN film or a SiON film that contains deuterium.

6. The tunable laser according to claim 1, further comprising:
a lower cladding layer that includes SiO₂ and is formed on a single crystal Si substrate, wherein
the optical modulation portion is disposed on the lower cladding layer.

7. The tunable laser according to claim 1, wherein
individual electrodes of the semiconductor gain portion and the optical modulation portion are disposed on a surface on the semiconductor gain portion side.
